(19) United States
(12) Patent Application Publication
(10) Pub. No.: US 2005/0204241 A1
(43) Pub. Date: Sep. 15, 2005

(54) Method and device for analyzing software error

(75) Inventor: Yasushi Tamakoshi, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/048,721

(22) Filed: Feb. 3, 2005

(30) Foreign Application Priority Data
Feb. 3, 2004 (JP) 2004-026351

(51) Int. Cl. G06F 11/00; G01R 31/28

(52) U.S. Cl. 714/741

(57) ABSTRACT

In a cause categorization step, bugs are categorized according to technical causes. In a damage evaluation step, how many steps the process has turned back due to a bug is measured. In a damage calculation step, damages are calculated for each bug technical cause. In a problem extraction step, a technical cause of which the damage is large is chosen as a problem. Then, in the bug database search step, a search for a measure for the bug technical cause extracted as a problem is performed with reference with a bug database so as to indicate an appropriate measure for a project.

### CROSS-REFERENCE TO RELATED APPLICATION

The disclosure of Japanese Patent Application No. 2004-26351 filed on Feb. 3, 2004 including specification, drawings and claims are incorporated herein by reference in its entity.

### BACKGROUND OF THE INVENTION

The present invention relates to bug analysis in software development processes, and particularly relates to bug analysis method and device which are helpful to measure planning in a software development process based on technical causes for bugs and damage of bugs on the progress of a project.

In a known software development project, there has been used a quality problem follow-up method and a support system which provide support for preventing re-occurrence of an inconvenience that has once occurred, in view of quality management (e.g., see Japanese Laid-Open Publication No. 2003-187069).

### SUMMARY OF THE INVENTION

However, the known technique has the following problems. In many cases, hundreds or a large number of bugs are discovered in a system test process, i.e., a lower process of development in a software development project. In the software development project, as a matter of course, it is necessary to identify causes of bugs one by one and correct errors in software. However, it is not realistic in terms of costs to plan a measure for every single bug in a software development process to prevent the occurrence of the same type of bugs, and also to implement the measure.

In view of the problem described above, the present invention has been devised. It is therefore an object of the present invention to improve a software development process in low costs by choosing a problem to which priority in problem resolution is to be given and planning a measure for the problem.

Specifically, the present invention is directed to a method for analyzing software error, the method including: a cause categorization step of categorizing bugs recorded in an electric bug form according to technical causes; a damage evaluation step of evaluating damages of the bugs on progress of a project; a damage calculation step of calculating damage amounts of the bugs for each bug technical cause; and a problem extraction step of choosing as a problem a bug technical cause of which the damage amount is large.

According to the present invention, the damage evaluation step may include the steps of: obtaining a bug discovery date and a bug correction verified date from the bug form; and calculating the number of days from the bug discovery date to the bug correction verified date.

According to the present invention, the inventive method may further include: an analysis result storage step of storing the damage amount of the bug technical cause in a bug database; a measure storage step of storing a measure for the bug technical cause in the bug database; and an effect storage step of storing an effect of the measure for the bug technical cause in the bug database.

According to the present invention, the inventive method may further include: a bug database search step of performing, for the bug technical cause chosen as a problem, a search for the damage amount, measure and effect stored in the bug database and outputting a result of the search.

According to the present invention, the bug database search step may further include the step of arranging records of the search in decreasing order of the damage amount, the step of arranging records of the search in decreasing order of the number of same measures or the step of arranging records of the search in decreasing order of effect.

Moreover, the present invention is directed to a device for analyzing software errors, the device including: a cause categorizer for categorizing bugs recorded in an electric bug form according to technical causes; a damage evaluator for evaluating damages of the bugs on progress of a project; a damage calculator for calculating damage amounts of the bugs for each technical cause; and a problem extractor for choosing as a problem a bug technical cause of which the damage amount is large.

According to the present invention, the damage evaluator may include: an extractor for obtaining a bug discovery date and a bug correction verified date from the bug form; and a calculator for calculating the number of days from the bug discovery date to the bug correction verified date.

According to the present invention, the inventive device may further include: an analysis result storage for storing the damage amount of the bug technical cause in a bug database; a measure storage for storing a measure for the bug technical cause in the bug database; and an effect storage for storing an effect of the measure for the bug technical cause in the bug database.

According to the present invention, the inventive device may further include: a bug database searcher for performing, for the bug technical cause chosen as a problem, a search for the damage amount, measure and effect stored in the bug database and outputting a result of the search.

According to the present invention, the bug database searcher may further include a sorter for arranging records of the search in decreasing order of the damage amount, a sorter for arranging records of the search in decreasing order of the number of same measures, or a sorter for arranging records of the search in decreasing order of effect.

As has been described, according to the bug analysis method and device of the present invention, problems of a project can be quantitatively understood. Furthermore, measure planning can be effectively performed by conducting a search, based on examples, for an appropriate measure for each problem of a project.

### BRIEF DESCRIPTION OF THE DRAWINGS

FIG. 1 is a flow chart illustrating a software development process according to an embodiment of the present invention.

FIG. 2 is a diagram illustrating a bug form according to an embodiment of the present invention.

FIG. 3 is a diagram illustrating a bug database according to an embodiment of the present invention.

FIG. 4 is a bug cause category table according to an embodiment of the present invention.

FIG. 5 is a diagram illustrating bug cause category input according to an embodiment of the present invention.

FIG. 6 is a table showing evaluation of damage amount according to an embodiment of the present invention.

FIG. 7 is a diagram showing data in a bug database according to an embodiment of the present invention.

### DESCRIPTION OF THE PREFERRED EMBODIMENTS

Hereinafter, embodiments of the present invention will be described with reference to the accompanying drawings. Preferred embodiments described in the following are not more than examples of the present invention and no way intended to limit the present invention and application or use of the present invention.

(1) Software Development Process

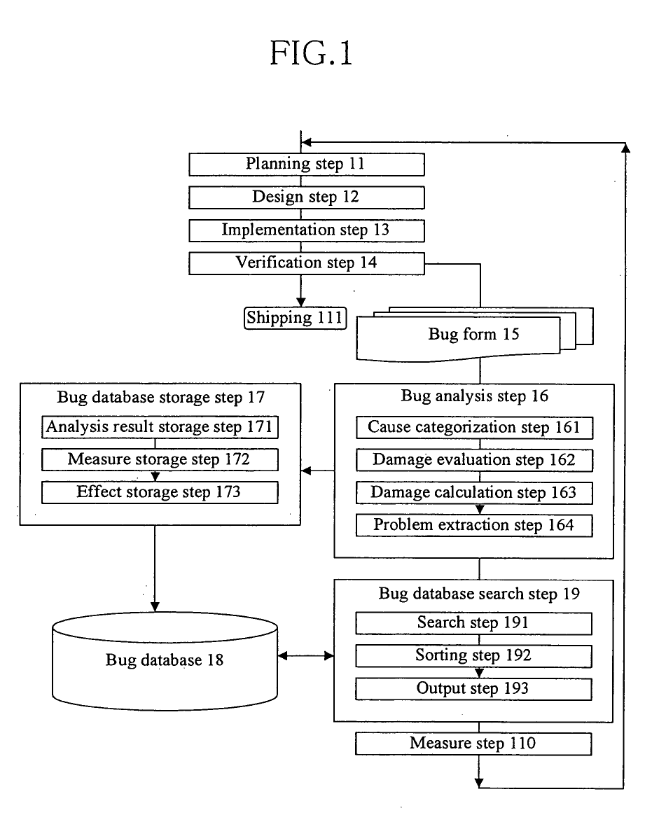

FIG. 1 is a flow chart showing a software development process using a device for analyzing software errors according to one embodiment of the present invention. In general, a software development process can be described with a so-called waterfall model in which development process proceeds in one direction. The waterfall model includes a planning step 11, a design step 12, an implementation step 13 and a verification step 14. It should be noted that a spiral model in which perfection of a system is improved by repeating the design step 12, the implementation step 13 and the verification step 14 while development process proceeds can be considered to be a modified form of the waterfall model.

Inappropriate design or implementation discovered in each process of a software development project is called a bug. In general, the later a process step in which bugs are discovered is, the higher costs for correction become. That is, in terms of costs, it is ideal that bugs are discovered and corrected in a process step in which the bugs have are mixed in. Bugs discovered in a system test in the verification step 14, i.e., a lower process in a software development process might turn back not only to the implementation step 13 of performing coding but also to the design step 12 of performing designing at the abstract level or even to the planning step 11 of defining requirements depending on the case. This causes large damage on a software development project in terms of development costs.

Bugs discovered in the system test of the verification step 14 are electrically recorded in a format called bug form 15.

If bugs are no longer discovered in the system test of the verification step 14, the software development project is completed and then completed software is shipped 111.

A process step of planning a measure for software development process by analyzing contents described in the bug form 15 and systematically arranging reflection points is called a bug analysis step 16. As for the bug analysis step 16, if the bug analysis step 16 is performed when the software development project is completed, a process of a next software development project can be improved. Also, if the bug analysis step 16 is performed in the middle of a software development project, processes of the ongoing software development project can be also improved.

The bug analysis step 16 includes a cause classification step 161 for categorizing bugs according to technical causes, the damage evaluation step 162 of measuring how many process steps bugs have turned back, the damage calculation step 163 of calculating the damage for each bug technical cause, and the problem extraction step 164 of identifying a bug technical cause which leads large damage.

When the software development project is terminated, analysis results by the bug analysis step 16 in the project are electrically recorded in the bug database 18 by a bug database storage step 17.

The bug database storage step 17 includes the analysis result storage step 171 of recording analysis results by the bug analysis step 16 in the bug database 18, a measure storage step 172 of recording a measure planned based on a problem in the previous project, and an effect storage step 173 of recording, as an effect of the measure, a reduction amount of damage due to a bug technical cause that has been identified as a problem.

The bug technical cause that has been identified as a problem by the bug analysis step 16 is a reflection for a next project and a measure for the technical cause is examined. In a bug database search step 19, a search for an appropriate measure is performed with reference to the bug database 18.

The bug database search step 19 includes a search step 191 of performing a search for a measure for a bug technical cause that has been identified as a problem, a sorting step 192 of arranging measures found by the search in decreasing order of effect, and an output step 193 of displaying a search result.

A measure planned in the measure step 110 in response to a support received from the bug database search step 19 is reflected in the planning step 11 in a next software development project or the ongoing software development project and is implanted in the designing step 12 and the implementation step 13. Thus, software development processes are improved.

(2) Bug Form

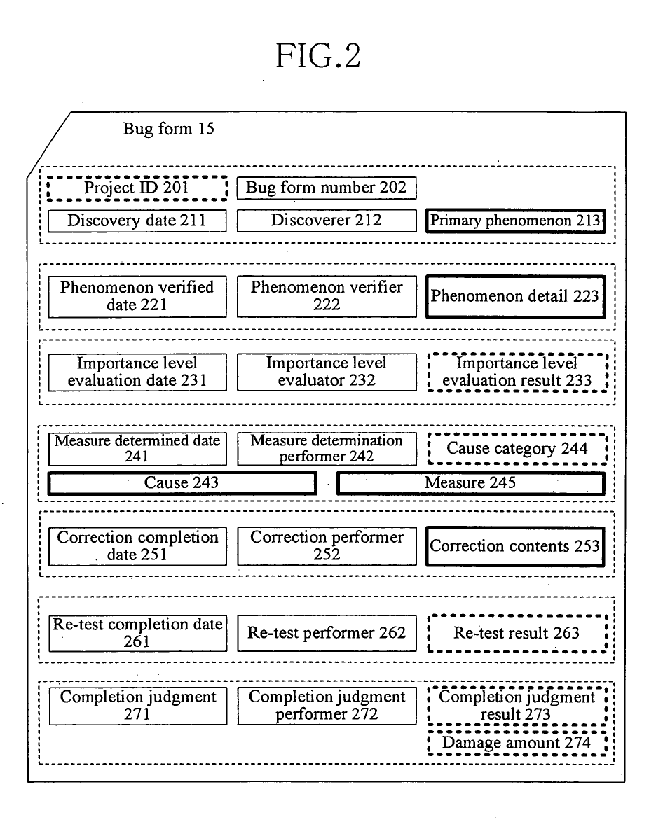

Hereinafter, a format of the bug form 15 and a bug correction process according to this embodiment will be described with reference to FIG. 2.

When a bug is discovered in the system test of the verification step 14, the bug form 15 is created by recording a project ID 201, a bug form number 202, a discovery date 211, a discoverer name 212 and a primary phenomenon 213. Then, when the primary phenomenon 213 is verified, the bug is identified by recording the phenomenon verified date 221, a phenomenon verifier name 222 and phenomenon details 223.

Next, when the level of importance of the bug is evaluated, priority in correction is determined by recording an importance level evaluation date 231, an importance level evaluation grader name 232 and an importance level evaluation result 233. Then, when cause and correction measure for the bug are identified, correction is started by recording a measure determined date 241, a measure determination performer name 242, a cause 243, a cause category 244 and a measure 245. When the correction is completed, a re-test is started by recording a correction completion date 251, a correction performer name 252, and correction contents 253. Furthermore, when the re-test is completed, completion judgment is started by recording a re-test completion date 261, a re-test performer name 262, and a re-test result 263. Then, when a completion judgment is performed, the correction process of the bug is terminated by recording a completion judgment date 271, a completion judgment performer name 272, a completion judgment result 273, and a damage amount 274.

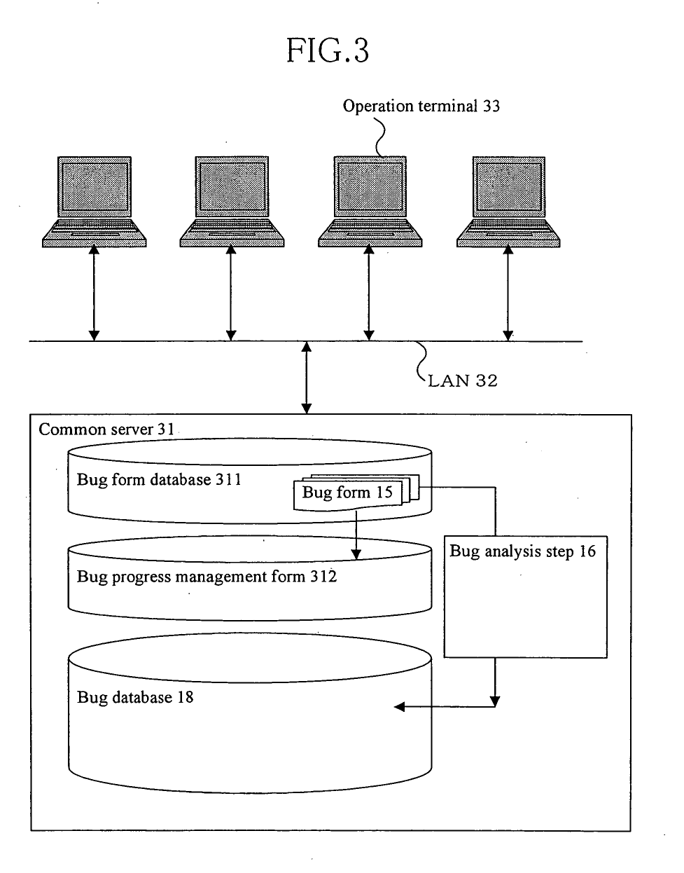

As shown in FIG. 3, in this embodiment, the bug form 15 is stored in a bug form database 311 provided on a common server 31 in the software development project. The common server 31 is accessible from an operation terminal 33 of each member of the software development project via a LAN 32. The common server 31 includes a bug form database 311, a bug progress management table 312, and a bug database 18. As described in the following, each member of the software development project accesses the bug database 311 and writes predetermined information in an electronic bug form 15.

When a system test performer discovers a bug in the system test of the verification step 14, the person logs in a tested system and selects a menu for bug form creation as shown in FIG. 2. Then, information for the discovery date 211 and the discoverer name 212 is automatically input from time information of the system and log-in information, respectively. Moreover, a project which the system test performer corresponding to the discoverer name 212 handles is displayed as a menu, and the system test performer selects the project ID 201 and inputs information for the project ID 201. When the project ID 201 is determined, a bug form number 202 is added and information for the bug form number 202 is automatically input. Thereafter, the system test performer inputs information for the primary phenomenon 213. In the manner described above, the bug form 15 is created.

Next, when the bug form 15 has been created, the created bug form information is mail transmitted to developer members of the project corresponding to the project ID 201. When a developer member of the project verifies the primary phenomenon 213 in a development environment, the member logs in the system and selects a menu for phenomenon verification. Then, information for the phenomenon verification date 221 and the phenomenon verifier name 222 is automatically input from the time information of the system and the log-in information, respectively. Thereafter, the developer member inputs information for the phenomenon detail 223. In the manner described above, the bug is identified.

Next, when the bug has been identified, the completed bug form information is mail transmitted to a project leader of the project corresponding to the project ID 201 and a representative for the project leader. When the project leader of the project or the representative for the project leader evaluates the level of importance of the bug, the project leader of the project or the representative logs in the system and selects a menu for importance level evaluation. Then, information for the importance level evaluation date 231 and the importance level evaluation grader name 232 is automatically input from the time information of the system and the log-in information, respectively. Thereafter, the project leader or the representative for the project leader selects and inputs information for the importance level evaluation result 233 from the menu.

Then, the completed bug form information is mail transmitted to the project leader of the project corresponding to the project ID 201 and the representative for the project leader and is also displayed in a bug progress management table 312 which will be described later with reference to FIG. 3. All members of the software development project can refer to the bug progress management table 312. In the bug progress management table 312, besides a progress state, information recorded in the bug form including the importance level evaluation result for the bug is displayed. A progress state of a bug that has been just identified is indicated as “under investigation”.

Next, the developer member of the project corresponding to the project ID 201 pursues a cause for the bug and plans a correction proposal. When the developer member of the project pursues a cause for the bug and plans a correction proposal, the developer member logs in the system and selects a menu for cause input. Then, information for the measure determined date 241 and the measure determination performer name 242 is automatically input from the time information and the log-in information, respectively. Thereafter, the developer member inputs information for the cause 243 and the measure 245 and selects and inputs the cause category 244 from a menu. Thus, the progress state of the bug is reflected in the bug progress management table 312 and the progress state of the bug is indicated as “correcting”.

Next, the developer member of the project corresponding to the project ID 201 performs correction. When the developer member of the project completes correction for the bug, the developer member logs in the system and selects a menu for correction completion. Then, information for the correction completion date 251 and the correction performer name 252 is automatically input from the time information of the system and the log-in information, respectively. Thereafter, the developer member inputs information for the correction contents 253. Thus, the progress state of the bug is reflected in the bug progress management table 312 and the progress state of the bug is indicated as “re-testing”.

Next, when the correction is completed, the completed bug form information is mail transmitted to the system test performer handling the project ID 201. When the system test performer of the project has completed the re-test, the system test performer logs in the system and selects a menu for re-test. Then, information for the re-test completion date 261 and the re-test performer name 262 is automatically input from the time information of the system and the log-in information, respectively. Thereafter, the system test performer selects and inputs information for the re-test result 263 from a menu. Thus, the progress state of the bug is reflected in the bug progress management table 312 and the progress state is indicated as “under determination”.

Next, when the re-test is completed, the completed bug form information is mail transmitted to the project leader of the project corresponding to the project ID 201 and the representative for the project leader. When the project leader of the project or the representative for the project leader has performed completion judgment, the project leader or the representative logs in the system and selects a menu for completion judgment. Then, information for the completion date 271 and the completion judgment performer name 272 is automatically input from the time information of the system and the log-in information, respectively. Thereafter, the project leader or the representative inputs information for a completion judgment result 273 and a damage amount 274. Thus, the progress state of the bug is reflected in the bug progress management table 312 and the correction process for the bug is completed.

Note that in FIG. 2, an automatic input portion, a menu input portion and a manual input portion by a user are expressed by a thin line, a thick broken line and a thick solid line, respectively.

(3) Omission of Bug Form Items

In the description above, the items of the bug form 15 in this embodiment have been shown. However, depending on an adopted software development standard, the bug form 15 used therein does not have to include all of the items described above. The bug form 15 including part of the items described above may be also used. In such a case, the bug correction process described above is partially omitted. It should be noted that the cause category 244 is a necessary item.

Moreover, in damage evaluation which will be described later, if the damage amount 274 is used, the damage amount 274 is a necessary item. Furthermore, if the number of days required for bug correction is used, the discovery date 211 and the completion judgment date 271 are necessary items. Depending on a software development standard to be adopted, the phenomenon verified date 221, instead of the discovery date 211, may be used as a necessary item, and the re-test completion date 261 and the correction completion date 251, instead of the completion judgment date 271, may be used as necessary items.

(4) Cause Categorization

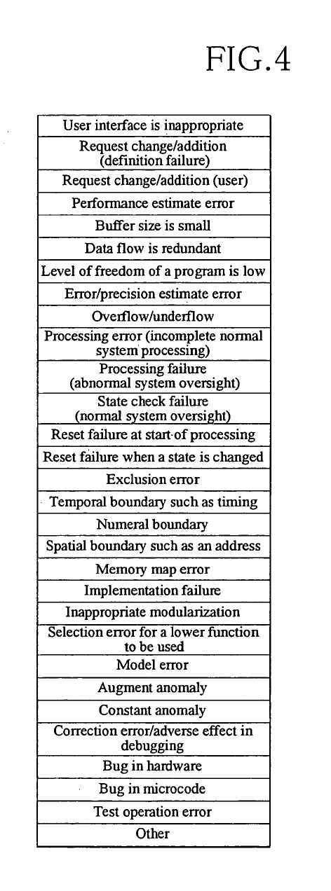

Categories for the cause category 244 of the bug form 15 in this embodiment are shown in a category table of FIG. 4. As for the cause category 244, categorization is performed using direct technical causes so as to link bugs to technical measures in a software development process.

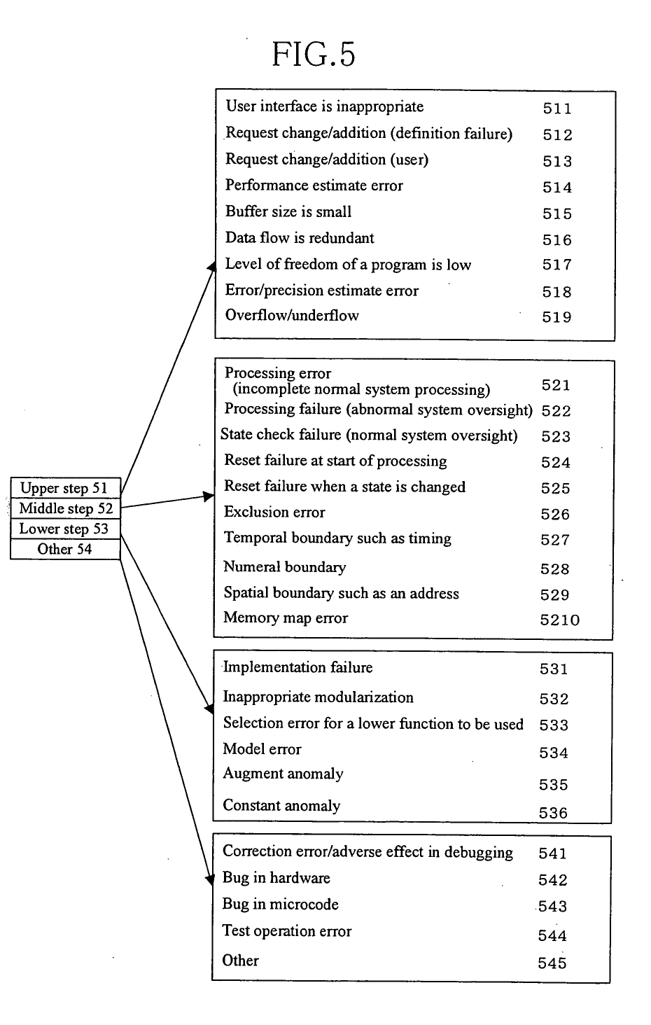

Hereinafter, with reference to FIG. 5, a cause input method according to this embodiment will be described. In inputting information for the cause category 244, a major category to be used in a software development process and the like is selected using a menu. Specifically, a user makes a selection from four categories, i.e., an upper process 51 such as request analysis, system designing and software architecture designing, a middle process 52 such as software function designing and software module designing, and a lower process 53 such as coding, and other 54 such as an error of test and a bug in software. When the major category has been selected, a menu including detail categories is continuously displayed. A detail category is a bug technical cause included in a major category in the software development process.

When the upper process 51 for the major category is selected, as detail categories, inappropriate 511, request change/addition (definition failure) 512, request change/addition (user) 513, performance estimate error 514, buffer size is small 515, data flow is redundant 516, the level of freedom of a program is low 517, error/precision estimate error 518 and overflow/underflow 519 are displayed in a menu, and the user selects one from the menu.

When the middle process 52 for the major category is selected, as detail categories, processing error (incomplete normal system processing) 521, processing failure (abnormal system oversight) 522, state check failure (normal system oversight) 523, reset failure at start of processing 524, reset failure when a state is changed 525, exclusion error 526, temporal boundary such as timing 527, numeral boundary 528, spatial boundary such as an address 529, memory map error 5210 are displayed in a menu, and the user selects one from the menu.

When the lower process 53 for the major category is selected, as detail categories, implementation failure 531, inappropriate modularization 532, selection error for a lower function to be used 533, model error 534, augment anomaly 535, and constant anomaly 536 are displayed in a menu, and the user selects one from the menu.

When other 54 for the major category is selected, as detail categories, correction error/adverse effect in debugging 541, bug in hardware 542, bug in microcode 543, test operation error 544, and other 545 are displayed in a menu, and the user selects one from the menu.

In this embodiment, as has been described, a total of about 30 types of bug technical causes are set as detail categories, and the detail categories are divided into four major categories. When the present invention is implemented, bug technical causes may be categorized in further detail within a range in which selection does not become complicated. In contrast, when there is some detail category considered to hardly occur as a bug technical cause, the detail category may be omitted from the detail category menu. However, it is not preferable to roughly set categories for the detail categorization because planning of a technical measure becomes difficult.

(5) Evaluation of Damage Amount

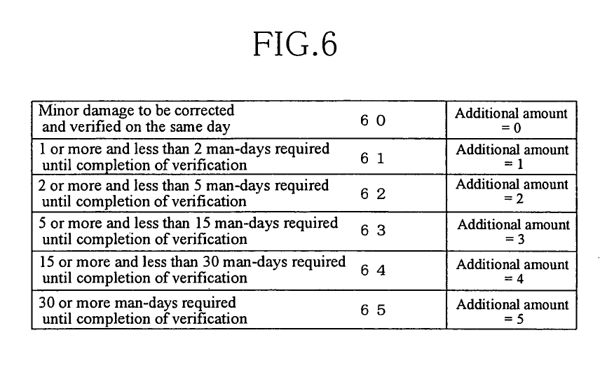

Next, a method for evaluating a damage amount in this embodiment of the present invention will be described with reference to FIG. 6. A user evaluates a damage given to a software development project by each bug and inputs an evaluation result into the damage amount 274 in the bug form 15. The damage is mainly a loss of man-hour/day for development but, for example, not a loss paid as a result of a bug.

In this embodiment, the following menu is displayed when input for the damage amount 274 is performed. Specifically, damages due to bugs are categorized into 6 stages, i.e., minor damage to be corrected and verified on the same day 60, 1 or more and less than 2 man-days were required until completion of verification 61, 2 or more and less than 5 man-days were required until completion of verification 62, 5 or more and less than 15 man-days were required until completion of verification 63, 15 or more and less than 30 man-days were required until completion of verification 64 and 30 or more man-days were required until completion of verification 65.

For each bug technical cause, as a damage, 0 is added to the damage amount for the bug cause if the damage is minor damage to be corrected and verified on the same day 60, 1 is added to the damage amount of the bug cause if one or more and less than two man-days were required until completion of verification 61, 2 is added to the damage amount of the bug cause if two or more and less than 5 man-days were required until completion of verification 62, 3 is added to the damage amount of the bug cause if 5 or more and less than 15 man-days were required until completion of verification 63, 4 is added to the damage amount of the bug cause if 15 or more and less than 30 man-days were required until completion of verification 64, and 5 is added to the damage amount of the bug cause if 30 or more man-days were required until completion of verification 65.

A method for evaluating a damage amount according to a different embodiment of the present invention from the one described above will be described with reference to FIG. 2.

The number of days from the discovery date 211 to the completion judgment date 271 described in the bug form 15 is added to the damage amount of the bug cause given to a project. In this embodiment, as a method for calculating the number of days from the discovery date 211 to the completion judgment date 271, merely, calendar days are used. However, the number of workdays of the project may be separately defined on the calendar so as to calculate the number of workdays excluding non-workdays such as holidays.

(6) Database Storage

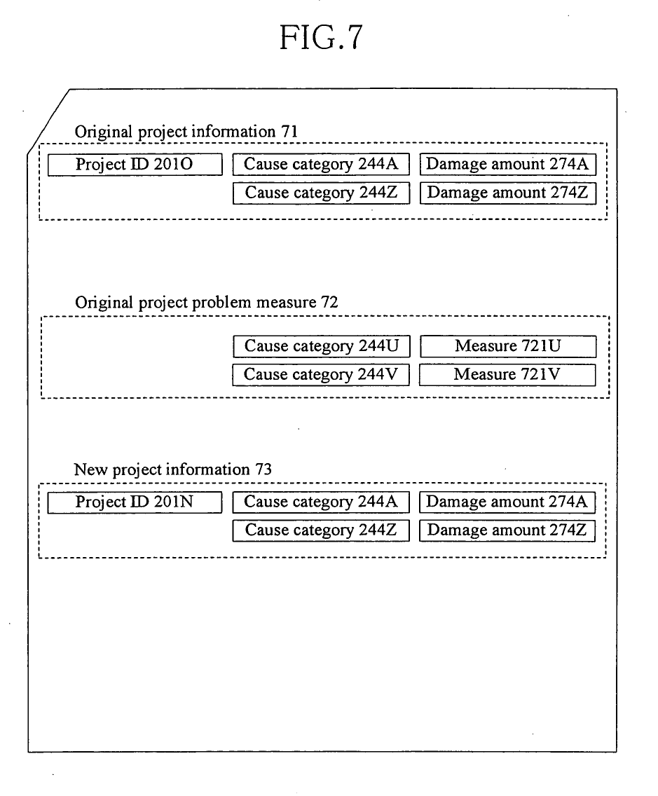

Next, a method for storing a database according to an embodiment of the present invention will be described with reference to FIG. 1, FIG. 3 and FIG. 7.

Each member of a software development project can access the bug form database 311, the bug progress management table 312 and the bug database 18 provided on the common server 31 from the operation terminal 33 of each member via a LAN 32.

As has been described, when a bug is discovered, the bug form 15 is created in the bug form database 311 and necessary items are written in the bug form 15 in order. Accordingly, as many bug forms 15 as the number of bugs are stored in the bug form database 311.

In each of bug forms 15 for the same project, the same value is described for the project ID 201. In the cause categorization step 161 of the bug analysis step 16, the bug forms 15 of the same project are categorized according to the cause category 244.

In the damage evaluation step 162 of the bug analysis step 16, the damage amount 274 of each of the bug forms 15 is assumed to be the damage amount of the bug. However, as has been described in “Evaluation of damage amount”, instead of the damage amount 274, the number of days from the discovery date 211 to the completion judgment date 271 may be assumed as the damage amount of the bug.

In the damage calculation step 163 of the bug analysis step 16, the damage amount of the bug is added for each category for the cause category 244. In the problem extraction step 164 of the bug analysis step 16, the cause category 244 of which the damage amount was large based on a calculation result of the damage calculation step 163 is extracted as a problem for the project.

In the bug database storage step 17, the bug analysis result is stored in the bug database 18. In an analysis result storage step 171 of the bug database storage step 17, original project information 71 including information for the project ID 201, information for the cause category 244 as the bug analysis result, and information for the damage amount 274 is stored in the bug database 18.

In a measure storage step 172 of the bug database storage step 17, a category for the cause category 244 extracted as a problem in the project ID 201 of the project and a measure 721 determined in the measure step 110 for a next project are stored as an original project problem measure 72 in the bug database 18.

In an effect storage step 173 of the bug database storage step 17, when in the project, the measure determined in the measure step 110 in bug analysis in a project performed prior to the project is implemented, as a result of the measure for the project ID 201 of the previous project, new project information 73 including information for the project ID 201, information for the cause category 244 as a bug analysis result and information for the damage amount 274 are stored in the bug database 18.

(7) Database Search

A method for performing a search in a database according to an embodiment of the present invention will be described with reference to FIG. 1 and FIG. 7. As described in the method for storing a database, a group of three items, i.e., the original project information 71 including a project ID 201O for the previous project, information for the cause category 244 as the bug analysis result and information for the damage amount 274, the original project problem measure 72 including a category for the cause category 244 extracted as a problem in bug analysis in the previous project and the measure 721 determined in the measure step 110, and the new project information 73 including a project ID 201N of a project in which the measure has been implemented, a category for the cause category 244 as the bug analysis result and information for the damage amount 274 is stored in the bug database 18 according to the number of projects.

In the bug database search step 19, a search for an appropriate measure for the problem of the project extracted in the problem extraction step 164 is performed in the bug database 18 in order to effectively provide a support for determining a measure to a next project in the measure step 110.

In the search step 191 of the bug database search step 19, a search for a record in which cause categories 244U and 244V of the original project problem measure 72 are the same as the cause category 244 to be a problem of the project extracted in the problem extraction step 164 is performed. In the sorting step 192 of the bug database search step 19, records are re-arranged in decreasing order of damage amounts 274A and 274Z corresponding to cause categories 244A and 244Z, respectively, included in the original project information 71 of a record found in the search by the search step 191. In the output step 193 of the bug database search step 19, results of the sorting step 192 are output for display in order.

It should be noted that in the sorting step 192, the method in which records are re-arranged in decreasing order of the damage amounts 274A and 274Z corresponding to the cause categories 244A and 244Z included in the original project information 71 of a record found in the search by the search step 191 has been used. However, the following methods or a combination of the following methods may be used.

As a second method, records are re-arranged in decreasing order of a value obtained by subtracting the damage amounts 274A and 274Z corresponding to the cause categories 244A and 244Z included in the new project information 73 from the damage amounts 274A and 274Z corresponding to the cause categories 244A and 244Z included in the original project information 71.

As a third method, records are re-arranged in decreasing order of a value obtained by subtracting the ratio of the damage amount 274A and 274Z corresponding to the cause categories 244A and 244Z included in the new project information 73 to a whole damage amount from the ratio of the damage amounts 274A and 274Z corresponding to the cause categories 244A and 244Z included in the original project information 71 to a whole damage amount.

As a fourth method, records are re-arranged in decreasing order of frequency of measures 721U and 721V included in a record found in the search by the search step 191.

A method and a device for analyzing a bug according to the present invention are useful as a tool for supporting process improvement of a software development project.

1. A method for analyzing software error, the method comprising of:
a cause categorization step of categorizing bugs recorded in an electric bug form according to technical causes;
a damage evaluation step of evaluating damages of the bugs on progress of a project;
a damage calculation step of calculating damage amounts of the bugs for each bug technical cause; and
a problem extraction step of choosing as a problem a bug technical cause of which the damage amount is large.

2. The method of claim 1, wherein the damage evaluation step includes the steps of:
obtaining a bug discovery date and a bug correction verified date from the bug form; and
calculating the number of days from the bug discovery date to the bug correction verified date.

3. The method of claim 1, further comprising the steps of:
an analysis result storage step of storing the damage amount of the bug technical cause in a bug database;
a measure storage step of storing a measure for the bug technical cause in the bug database; and
an effect storage step of storing an effect of the measure for the bug technical cause in the bug database.

4. The method of claim 3, further comprising: a bug database search step of performing, for the bug technical cause chosen as a problem, a search for the damage amount, measure and effect stored in the bug database and outputting a result of the search.

5. The method of claim 4, wherein the bug database search step further includes the step of arranging records of the search in decreasing order of the damage amount.

6. The method of claim 4, wherein the bug database search step further includes the step of arranging records of the search in decreasing order of the number of same measures.

7. The method of claim 4, wherein the bug database search step further includes the step of arranging records of the search in decreasing order of effect.

8. A device for analyzing software errors, the device comprising:
a cause categorizer for categorizing bugs recorded in an electric bug form according to technical causes;
a damage evaluator for evaluating damages of the bugs on progress of a project;
a damage calculator for calculating damage amounts of the bugs for each technical cause; and
a problem extractor for choosing as a problem a bug technical cause of which the damage amount is large.

9. The device of claim 8, wherein the damage evaluator includes: an extractor for obtaining a bug discovery date and a bug correction verified date from the bug form; and
a calculator for calculating the number of days from the bug discovery date to the bug correction verified date.

10. The device of claim 8, further comprising:
an analysis result storage for storing the damage amount of the bug technical cause in a bug database;
a measure storage for storing a measure for the bug technical cause in the bug database; and
an effect storage for storing an effect of the measure for the bug technical cause in the bug database.

11. The device of claim 8, further comprising: a bug database searcher for performing, for the bug technical cause chosen as a problem, a search for the damage amount, measure and effect stored in the bug database and outputting a result of the search.

12. The device of claim 11, wherein the bug database searcher further includes a sorter for arranging records of the search in decreasing order of the damage amount.

13. The device of claim 11, wherein the bug database searcher further includes a sorter for arranging records of the search in decreasing order of the number of same measures.

14. The method of claim 11, wherein the bug database searcher further includes a sorter for arranging records of the search in decreasing order of effect.
